(19) United States
(12) Patent Application Publication
(10) Pub. No.: US 2026/0068040 A1
(43) Pub. Date: Mar. 5, 2026

(54) STRETCHABLE WIRING BOARD AND STRETCHABLE DEVICE USING SAME

(71) Applicant: TDK CORPORATION, Tokyo (JP)

(72) Inventors: Kazutaka TAMAKI, Tokyo (JP); Hajime AZUMA, Tokyo (JP)

(73) Assignee: TDK CORPORATION, Tokyo (JP)

(21) Appl. No.: 19/120,906

(22) PCT Filed: Mar. 21, 2024
(86) PCT No.: PCT/JP2024/011130

§ 371 Date: Apr. 14, 2025

(30) Foreign Application Priority Data
Mar. 30, 2023 (JP) 2023-055097

(51) Int. Cl. H05K 1/02; H05K 1/09

(52) U.S. Cl. CPC H05K 1/0283; H05K 1/09

(57) ABSTRACT

This stretchable wiring board includes: a stretchable insulating substrate containing a resin; and a stretchable wiring that contains a resin and is formed on a main surface of the stretchable insulating substrate, in which the stretchable wiring has a plurality of linear portions extending linearly in multiple different directions, and bent portions that connect the linear portions extending in the different directions, and the bent portions have a rectangular section and a recessed triangular portion which is positioned on an inner contour side of the inner contour and an outer contour constituting its outer shape and is surrounded by two slanted edges and a recessed arc-shaped bottom edge when viewed in plan view.

### TECHNICAL FIELD

The present invention relates to a stretchable wiring board and a stretchable device using the same.

Priority is claimed on Japanese Patent Application No. 2023-055097, filed Mar. 30, 2023, the content of which is incorporated herein by reference.

### BACKGROUND ART

In recent years, along with the development of flexible sensors, wearable devices capable of managing physical condition have been attracting attention.

Wearable devices are expected to have a wide range of applications in the fields of sports science and healthcare, where they are designed to measure and monitor specific parts of the body such as those directly attached to the skin or those built into clothing. Since human skin is repeatedly stretched and contracted on a daily basis, it is desirable for a wearable device to be stretchable in response to the object on which it is worn if stress-free wearability is desired for the wearable device. In addition, it is desirable that the wearable device have a strength at a certain level or higher against stress generated during its bending and rolling, assuming its handling or human movement. Devices with such a characteristic are referred to as stretchable devices in the present specification, with their use not limited to wearable devices.

Stretchable devices are assumed to include electrodes, wiring, devices, electronic components, thin-film sensors, and the like within stretchable elements, and it is necessary for them to maintain their quality even in a use environment where stretching and contracting are repeated. However, it is difficult to realize such stretchable devices with polyimide sheets used in conventional thin-film resin boards. For this reason, it is assumed that resins, such as urethane resins, silicone resins, acrylic resins, epoxy resins, polycarbonates, polystyrene, and polyolefins, corresponding to stretchability will be used as main constituent materials for elements and electrodes in stretchable devices. Among these, it is thought that a stretchable film which is a cured product of a composition containing a (meth)acrylate compound with a siloxane bond, a (meth)acrylate compound, other than the (meth)acrylate compound, that has a urethane bond, and an organic solvent with a boiling point in a range of 115° C. to 200° C. at atmospheric pressure and in which the (meth)acrylate compound with a siloxane bond is unevenly distributed on the film surface has excellent stretchability and strength comparable to those of polyurethanes, and the film surface has excellent water repellency comparable to that of silicones (refer to Patent Document 1).

Regarding a wiring board used in a stretchable device, when the wiring board is bent, only the center of the wiring board remains unstressed, whereas compressive stress acts on the inner side of the wiring board and tensile stress acts on the outer side of the wiring board. In other words, contraction stress acts on the inner side of the wiring board, while elongation stress acts on the outer side of the wiring board. At this time, contraction and elongation stresses will also act on the wiring on the top surface of the wiring board, raising concerns that the resistance value of the wiring will change significantly and that the wiring will be damaged, such as by bending, cracking, or fracturing.

Known countermeasures to prevent such damage to wiring include forming horseshoe-shaped wiring on a stretchable substrate (for example, refer to Patent Document 2) and forming bellows-shaped wiring on a stretchable substrate (for example, refer to Patent Document 3). In addition, Patent Document 3 describes that the bellows-shaped wiring can suppress changes in the resistance value of the wiring.

### CITATION LIST

### Patent Documents

Patent Document 1: Japanese Unexamined Patent Application, First Publication No. 2017-206626
Patent Document 2: Japanese Unexamined Patent Application, First Publication No. 2013-187308
Patent Document 3: Japanese Unexamined Patent Application, First Publication No. 2020-136278

### SUMMARY OF INVENTION

### Technical Problem

However, in the case of the resin sheet (resin film) made mainly of a cured product of a resin composition as described in Patent Document 1, if the curing reaction does not proceed uniformly, there is a problem that variations in composition and degree of curing may occur in the resin sheet, resulting in the sheet not having desired stretchability, strength, and aging degradation resistance characteristics.

In addition, there is a concern that the horseshoe or bellows shape of the wiring may make the board vulnerable to repeated stretching and contracting motion.

To realize stretchable devices, there is a demand for stretchable wiring boards in which cracks and fractures in wiring caused by repeated stretching and contracting motion of the boards are reduced. In addition, there is a demand for a stretchable wiring board having wiring that exhibits minimal change in conductivity when stretched.

The present invention has been made in consideration of the above-described circumstances, and an object of the present invention is to provide a stretchable wiring board and a stretchable device in which cracks and fractures of wiring caused by repeated stretching and contracting motion of the board are reduced.

### Solution to Problem

The present invention provides the following means to solve the above-described problems.

Aspect 1 of the present invention is a stretchable wiring board including: a stretchable insulating substrate containing a resin; and a stretchable wiring that contains a resin and is formed on a main surface of the stretchable insulating substrate, in which the stretchable wiring has a plurality of linear portions extending linearly in multiple different directions, and bent portions that connect the linear portions extending in the different directions, and the bent portions have a rectangular section and a recessed triangular portion which is positioned on an inner contour side of the inner contour and an outer contour, which constitute its outer shape, and is surrounded by two slanted edges and a recessed arc-shaped bottom edge when viewed in plan view.

Aspect 2 of the present invention is a stretchable wiring board including: a stretchable insulating substrate containing a resin; and a stretchable wiring that contains a resin and is formed on a main surface of the stretchable insulating substrate, in which the stretchable wiring has a plurality of linear portions extending linearly in multiple different directions, and bent portions that connect the linear portions extending in the different directions, and the bent portions have a rectangular section and an arcuate portion which is positioned on an outer contour side of an inner contour and the outer contour, which constitute its outer shape, and is surrounded by an arc (having a central angle of less than) 180° and a chord connecting both end points of the arc when viewed in plan view.

As Aspect 3 of the present invention, in the stretchable wiring board of Aspect 1, the bent portions further have an arcuate portion which is positioned on the outer contour side and is surrounded by an arc (having a central angle of less than 180°) and a chord connecting both end points of the arc when viewed in plan view.

As Aspect 4 of the present invention, in the stretchable wiring board according to Aspect 1 or 3, when the line width of two linear portions forming each of the bent portions is D and the radius of curvature of the recessed arc-shaped bottom edge is R1, the relational expression 0.5≤L1≤2 holds when L1=R1/D.

As Aspect 5 of the present invention, in the stretchable wiring board according to Aspect 2, when the line width of two linear portions forming each of the bent portions is D and the radius of curvature of the recessed arc-shaped bottom edge is R1, the relational expression 0.5≤L1≤2 holds when L1=R1/D.

As Aspect 6 of the present invention, in the stretchable wiring board according to any one of Aspects 1, 3, and 4, the line width D of two linear portions forming each of the bent portions is 3 mm or less.

As Aspect 7 of the present invention, in the stretchable wiring board according to Aspect 2 or 5, the line width D of two linear portions forming each of the bent portions is 3 mm or less.

As Aspect 8 of the present invention, in the stretchable wiring board according to any one of Aspects 1, 3, 4, and 6, the stretchable wiring contains a resin and flake-shaped metal powder, has an elongation at break of 130% or more, and has a resin percentage of 8 wt % to 20 wt %.

As Aspect 9 of the present invention, in the stretchable wiring board according to any one of Aspects 2, 5, and 7, the stretchable wiring contains a resin and flake-shaped metal powder, has an elongation at break of 130% or more, and has a resin percentage of 8 wt % to 20 wt %.

As Aspect 10 of the present invention, in the stretchable wiring board according to any one of Aspects 1, 3, 4, 6, and 8, the stretchable wiring contains a resin having a monomer unit structure identical to that of the resin.

As Aspect 11 of the present invention, in the stretchable wiring board according to any one of Aspects 2, 5, 7, and 9, the stretchable wiring contains a resin having a monomer unit structure identical to that of the resin.

Aspect 12 of the present invention is a stretchable device in which the stretchable wiring board according to any one of Aspects 1 to 11 is used.

### Advantageous Effects of Invention

According to the present invention, it is possible to provide a stretchable wiring board in which cracks and fractures in wiring caused by repeated stretching and contracting motion of the board are reduced.

### BRIEF DESCRIPTION OF DRAWINGS

FIG. 1 A schematic plan view showing a portion of a stretchable wiring board according to an embodiment.

FIG. 2 A schematic cross-sectional view taken along the section cut at I-I′ in FIG. 1.

FIG. 3A An enlarged schematic plan view of the vicinity of a bent portion shown in FIG. 1.

FIG. 3B An enlarged view of only a recessed triangular portion constituting the bent portion in FIG. 3A.

FIG. 4A A schematic plan view of a modified example of the bent portion shown in FIG. 3A.

FIG. 4B An enlarged view of only an arcuate portion constituting the bent portion in FIG. 4A.

FIG. 5A A schematic plan view of another modified example of the bent portions shown in FIGS. 3A and 4A.

FIG. 5B An enlarged view of only an arcuate portion constituting the bent portion in FIG. 5A.

FIG. 6A A plan view showing 20 examples of various bent portions, which are CAD-designed, and their configurations (including two linear portions forming each bent portion).

FIG. 6B A photograph of samples of the bent portions (including two linear portions forming each bent portion) actually produced corresponding to the CAD design shown in FIG. 6A.

FIG. 7A A plan view showing the configurations of the CAD-designed bent portions (including two linear portions forming each bent portion).

FIG. 7B A photograph of samples of the bent portions (including two linear portions forming each bent portion) actually produced corresponding to the CAD design shown in FIG. 7A.

### DESCRIPTION OF EMBODIMENT

Hereinafter, the present invention will be described in detail with appropriate reference to the drawings. In the drawings used in the following description, a part that becomes a feature is sometimes enlarged for convenience in order to allow the feature to be easily understood, and the dimensional ratios of each constituent element and the like are sometimes different from the actual ones. The materials, dimensions, and the like exemplified in the following description are merely examples, and the present invention is not limited thereto and can be implemented by being appropriately modified within the range in which the effect of the present invention is exhibited.

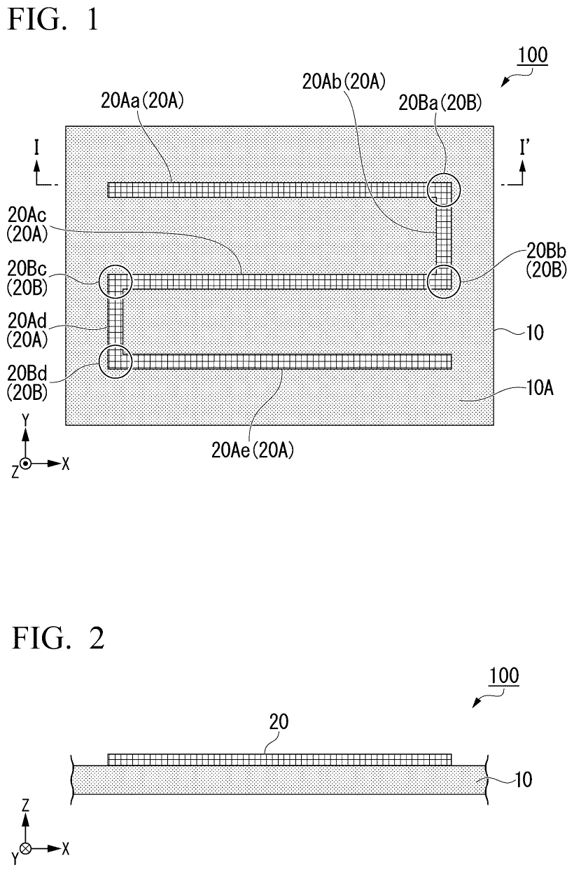

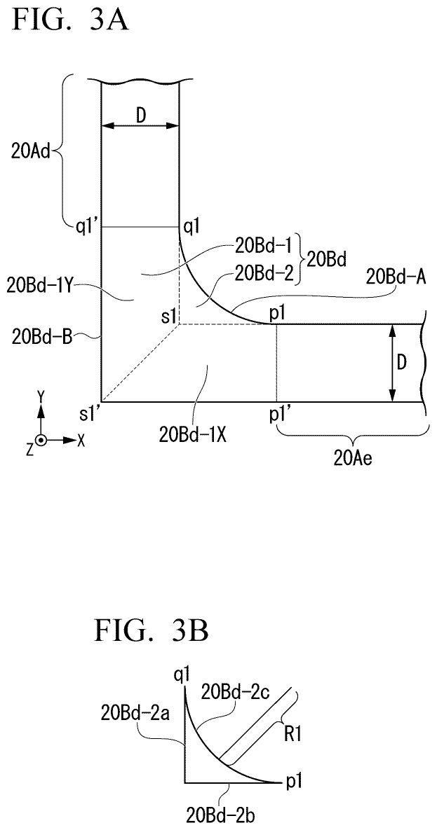

FIG. 1 is a schematic plan view showing a portion of a stretchable wiring board according to an embodiment. FIG. 2 is a schematic cross-sectional view taken along the section cut at I-I′ in FIG. 1. FIG. 3A is an enlarged schematic plan view of the vicinity of a bent portion shown in FIG. 1.

A stretchable wiring board 100 shown in FIG. 1 includes a stretchable insulating substrate 10 containing a resin, and a stretchable wiring 20 that contains a resin and is formed on a main surface 10A of the stretchable insulating substrate 10.

The stretchable wiring 20 has various patterns depending on the application. Hereinafter, a stretchable wiring pattern 20 may be used as an example thereof.

### <Stretchable Insulating Substrate>

A well-known stretchable insulating substrate can be used as the stretchable insulating substrate 10.

A well-known stretchable resin can be used as the resin in the stretchable insulating substrate 10. Examples thereof include epoxy resins, urethane resins, urea resins, polyurethane urea resins, methacrylic acid resins, polyacrylic resins, silicone resins, diene resins, polyester resins, polyether resins, polyamide resins, and polystyrene resins.

The resin used in the stretchable insulating substrate 10 is preferably soluble in any one or more solvents selected from N,N-dimethylacetamide (DMAc), methyl ethyl ketone (MEK), N,N-dimethylformamide (DMF), diethylene glycol monobutyl ether, diethylene glycol monobutyl ether acetate (BCA), diethylene glycol monoethyl ether acetate, diethylene glycol monomethyl ether acetate, acetone, ethanol, methanol, ethyl lactate, butyl lactate, toluene, isopropyl alcohol, isobutyl alcohol, ethyl acetate, and butyl acetate.

The stretchable insulating substrate 10 may be formed by applying and solidifying a resin composition containing a solvent and the resin used in the above-described stretchable insulating substrate 10.

Among the above-described resins, a urethane resin that can be molded by simply applying and drying a resin composition without a curing reaction is preferable. This is because, with resins that require a curing reaction, if the curing reaction does not proceed uniformly, variations in composition and degree of curing may occur in resin sheets, resulting in resins that do not have desired stretchability, strength, and aging degradation resistance characteristics.

In addition, when a urethane resin is used, it is preferable that the resin component have a siloxane bond. This is because in this case, the resin composition has moderate water repellency, which inhibits hydrolysis of urethane bonds.

The elongation of the stretchable insulating substrate 10 can be appropriately set according to the elongation required for the application. The elongation can be adjusted, for example, by increasing the amount of stretchable resin to increase the elongation. In addition, the elongation can be adjusted by increasing the mol % of bonds with high elongation in the resin.

For example, the elongation of the stretchable insulating substrate 10 can be increased by increasing the percentage of urethane bonds in the resin. When the resin contains a urethane resin, the percentage of urethane bonds in the resin is preferably 15 wt % or more.

The percentage of urethane bonds in the resin can be calculated, for example, by calculating the peak surface area corresponding to the urethane bonds in the C¹³ nuclear magnetic resonance (NMR) spectrum.

The stretchable insulating substrate 10 preferably has an elongation at break of 20% or more. The elongation at break is more preferably 50% or more, still more preferably 100% or more, and most preferably 150% or more.

The “elongation at break” in the present specification is |{(L_{D}−L₀)/L₀}×100| (L₀: the length in the tensile direction before testing, L_{D}: the length at break). The “elongation at break” is evaluated as an absolute value. Although the elongation can be determined for each given direction, in this specification, the “elongation at break” refers to the elongation in the direction in which the elongation at break is the highest. If there is no anisotropy in the elongation, the elongation at break will be uniform in all directions, and if the anisotropy in the elongation is small, the elongation at break will have values close to each other in all directions.

The elongation at break can be measured as follows. Ten strip-like measurement samples of 10 mm wide and 30 mm long are cut out from a sheet-like sample of the stretchable insulating substrate and prepared. For each measurement sample, the elongation at break is calculated through a method shown below, and an average value thereof is taken as an elongation at break. A metal board is clamped between upper and lower gripping portions of a tensile tester (for example, product name: Autograph AGS-5kNX, manufactured by Shimadzu Corporation), and each measurement sample is fixed to the metal board with double-sided tape so that the measurement area is 10 mm wide and 10 mm long. Thereafter, each measurement sample is pulled at a tensile speed of 10 mm/min using a tensile tester. The length of each measurement sample at break is then measured, and the length before pulling, 10 mm, is subtracted from that length to calculate the elongation at break of each measurement sample. An average value thereof is taken as an elongation at break, and the elongation at break is calculated according to the above-described definition.

The thickness of the stretchable insulating substrate 10 is not limited, but as a guideline, for example, a thickness of 10 to 300 μm can be used.

### <Stretchable Wiring>

The stretchable wiring 20 shown in FIG. 1 has a plurality of linear portions 20A (20Aa, 20Ab, 20Ac, 20Ad, and 20Ae) extending linearly in multiple different directions and bent portions 20B (20Ba, 20Bb, 20Bc, and 20Bd) that connect the linear portions extending in the different directions. In the stretchable wiring 20 shown in FIG. 1, the number of linear portions is five and the number of bent portions is four. However, the numbers of linear portions and bent portions may be selected arbitrarily depending on the application, and the number of linear portions may be the same as or different from the number of bent portions.

The bent portion 20Ba is positioned at a section where the linear portion 20Aa extending in the X-direction connects with the linear portion 20Ab extending in the Y-direction. The bent portion 20Bb is positioned at a section where the linear portion 20Ab extending in the Y-direction connects with the linear portion 20Ac extending in the X-direction. The bent portion 20Bc is positioned at a section where the linear portion 20Ac extending in the X-direction connects with the linear portion 20Ad extending in the Y-direction. The bent portion 20Bd is positioned at a section where the linear portion 20Ad extending in the Y-direction connects with the linear portion 20Ae extending in the X-direction.

The structure of a bent portion will be described in detail with reference to FIG. 3A, which shows an enlarged view of the vicinity of the bent portion 20Bd among the bent portions 20B shown in FIG. 1 as an example. FIG. 3B shows only the recessed triangular portion that constitutes the bent portion.

As shown in FIGS. 3A and 3B, the bent portion 20Bd consists of a rectangular section 20Bd-1 and a recessed triangular portion 20Bd-2 which is positioned on an inner contour side 20Bd-A of the inner contour 20Bd-A and an outer contour 20Bd-B, which constitute its outer shape, and is surrounded by two slanted edges 20Bd-2a and 20Bd-2b and a recessed arc-shaped bottom edge 20Bd-2c when viewed in plan view.

The term “arc-shaped” in the arc-shaped bottom edge 20Bd-2c is not limited to a case of a substantially arc-like shape sufficient to define a radius of curvature (“R1” in FIG. 3B), but may be any shape with a smoothly varying inclination.

In the stretchable wiring 20, by providing the recessed triangular portion at the bent section (inside) as an additional stretchable wiring material, cracks are less likely to occur.

The rectangular section 20Bd-1 consists of a rectangular portion 20Bd-1Y extending in the Y-direction and a rectangular portion 20Bd-1X extending in the X-direction. In the configuration shown in FIG. 3A, the rectangular portion 20Bd-1Y is connected to the linear portion 20Ad with the same line width D, and the rectangular portion 20Bd-1X is also connected to the linear portion 20Ae with the same line width D. That is, the rectangular portion 20Bd-1Y and the rectangular portion 20Bd-1X both have the line width D.

The boundary between the rectangular portion 20Bd-1X of the bent portion 20Bd and the linear portion 20Ae is a line connecting an intersection p1 between the arc-shaped bottom edge 20Bd-2c and the linear portion 20Ad and a point p1′ in the width direction of the linear portion 20Ae. Similarly, the boundary between the rectangular portion 20Bd-1Y of the bent portion 20Bd and the linear portion 20Ad is a line connecting an intersection q1 between the arc-shaped bottom edge 20Bd-2c and the linear portion 20Ad and a point q1′ in the width direction of the linear portion 20Ad.

In addition, the boundary between the rectangular portion 20Bd-1X and the rectangular portion 20Bd-1Y (the boundary defined for convenience to clarify the definition) is the line connecting an inner bending point s1 and an outer bending point s1′ (the line indicated by the dotted line in FIG. 3A).

The bent portions 20B can be formed through a well-known technique and can be applied, for example, through well-known methods using various coaters, wire bars, or the like, or through various printing methods including inkjet printing methods.

The bent portions 20B formed through these methods can be formed integrally with the linear portions 20A. In the case where the bent portions 20B and the linear portions 20A can be integrally formed, the boundary between the bent portion 20Bd and the linear portion 20Ad shown in FIG. 3A is merely a boundary defined for convenience of explanation. Similarly, the 2Bd-1 and the recessed triangular portion 20Bd-2 that constitute the bent portion 20B can be integrally formed. In this case as well, the boundary between the rectangular section 20Bd-1 and the recessed triangular portion 20Bd-2 is merely a boundary defined for convenience of explanation.

On the other hand, instead of integrally forming the entire stretchable wiring, it can be divided into sections and formed separately.

For example, when forming the bent portion 20B, only the rectangular section 20Bd-1 constituting the bent portion 20B can be formed integrally with the linear portion 20A, and the recessed triangular portion 20Bd-2 constituting the bent portion 20B may be formed separately. Specifically, the rectangular section 20Bd-1 and linear portion 20A that constitute the bent portion 20B are printed first, and then the recessed triangular portion 20Bd-2 constituting the bent portion 20B is printed, whereby the rectangular section 20Bd-1 and recessed triangular portion 20Bd-2 that constitute the bent portion 20B can be formed separately.

When the rectangular section 20Bd-1 and the recessed triangular portion 20Bd-2 are formed separately in this manner, it becomes possible to change the materials. For example, when printing using conductive paste containing a resin and conductive filler as a material for the stretchable wiring, the rectangular section 20Bd-1 can be printed together with the linear portion 20A using conductive paste with a higher percentage of conductive filler with an emphasis on conductivity, while the recessed triangular portion 20Bd-2 can be printed using conductive paste with a higher percentage of resin with an emphasis on stretchability.

As described above, the rectangular section 20Bd-1 and recessed triangular portion 20Bd-2 that constitute the bent portion 20B can be made of the same material, or can be made of different materials, for example, with different composition ratios. When changing the composition ratios, it should be adjusted to a level that does not lead to cracks or damage. Materials having different types of conductive fillers may be used without changing the percentage of the resin and the conductive filler.

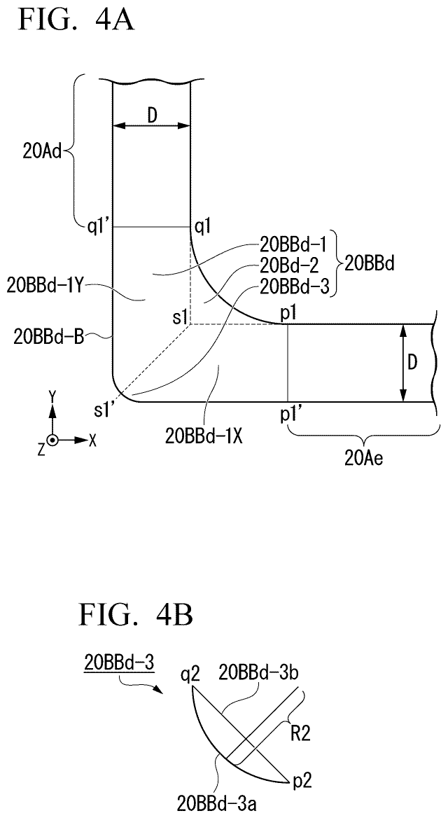

FIG. 4A is a schematic plan view of a modified example of the bent portion shown in FIG. 3A. FIG. 4B is an enlarged view of only an arcuate portion constituting the bent portion.

As shown in FIGS. 4A and 4B, a bent portion 20BBd consists of a rectangular section 20BBd-1, a recessed triangular portion 20Bd-2 surrounded by two slanted edges 20Bd-2a and 20Bd-2b and a recessed arc-shaped bottom edge 20Bd-2c when viewed in plan view, and an arcuate portion 20BBd-3 which is positioned on an outer contour 20BBd-B side and is surrounded by an arc (having a central angle of less than 180°) 20BBd-3a and a chord 20BBd-3b connecting both end points p and q of the arc 20BBd-3a when viewed in plan view.

The term “arc” in the arc (having a central angle of less than 180°) 20BBd-3a is not limited to a case of a strict arc sufficient to define a radius of curvature (“R2” in FIG. 4B), but may have any arc-like shape with a smoothly varying inclination.

In the stretchable wiring 20, by providing the arcuate portion at the bent section (outside) as an additional stretchable wiring material in addition to the recessed triangular portion provided at the bent section (inside), cracks are less likely to occur.

The rectangular section 20BBd-1 consists of a rectangular portion 20BBd-1Y extending in the Y-direction and a rectangular portion 20BBd-1X extending in the X-direction. Similarly to the configuration shown in FIG. 3A, in the case of the configuration shown in FIG. 4A, the rectangular portion 20BBd-1Y is connected to the linear portion 20Ad with the same line width D, and the rectangular portion 20BBd-1X is also connected to the linear portion 20Ae with the same line width D. That is, the rectangular portion 20BBd-1Y and the rectangular portion 20BBd-1X both have the line width D.

The boundary between the rectangular portion 20BBd-1X of the bent portion 20BBd and the linear portion 20Ae is a line connecting an intersection p1 between the arc-shaped bottom edge 20BBd-2c and the linear portion 20Ad and a point p1′ in the width direction of the linear portion 20Ae. Similarly, the boundary between the rectangular portion 20BBd-1Y of the bent portion 20BBd and the linear portion 20Ad is a line connecting an intersection q1 between the arc-shaped bottom edge 20BBd-2c and the linear portion 20Ad and a point q1′ in the width direction of the linear portion 20Ad.

In addition, the boundary between the rectangular portion 20BBd-1X and the rectangular portion 20BBd-1Y (the boundary defined for convenience to clarify the definition) is the line connecting an inner bending point s1 and a virtual outer bending point s1′ (the line indicated by the dotted line in FIG. 4A). Here, to supplement the explanation regarding the “virtual outer bending point s1′,” the bent portion 20BBd shown in FIG. 4A has an arcuate portion 20BBd-3, and therefore, the bent portion 20BBd does not have the outer bending point s1′ as shown in FIG. 3A. However, for convenience, the same point as the outer bending point s1′ shown in FIG. 3A is illustrated as the virtual outer bending point s1′ and is used for convenience in defining the definition.

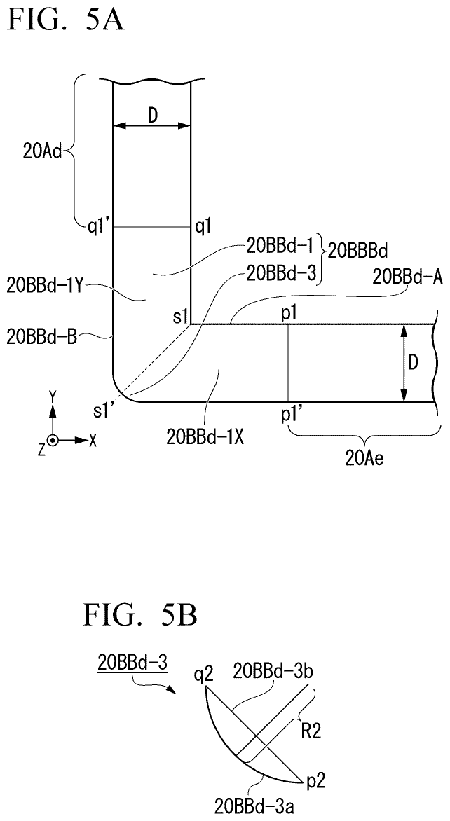

FIG. 5A is a schematic plan view of another modified example of the bent portions shown in FIGS. 3A and 4A, and FIG. 5B is an enlarged view of only an arcuate portion constituting the bent portion. The bent portion shown in FIG. 3A has a structure including a recessed triangular portion as an additional stretchable wiring material on the inner side of the bent portion, and the bent portion shown in FIG. 4A has a structure including, in addition to the recessed triangular portion shown in FIG. 3A, an arcuate portion as an additional stretchable wiring material on the outer side of the bent portion. Meanwhile, the bent portion shown in FIG. 5A has a structure including an arcuate portion as an additional stretchable wiring material on the outer side of the bent portion.

The bent portion 20BBBd shown in FIG. 5A is composed of a rectangular portion 20BBd-1 and an arcuate portion 20BBd-3 which is positioned on an outer contour 20BBd-B side between an inner contour 20BBd-A and the outer contour 20BBd-B, which constitute its outer shape, and is surrounded by an arc (having a central angle of less than 180°) 20BBd-3a and a chord 20BBd-3b connecting both end points p2 and q2 of the arc 20BBd-3a when viewed in plan view.

In the stretchable wiring 20, by providing the arcuate portion at the bent section (outside) as an additional stretchable wiring material, cracks are less likely to occur.

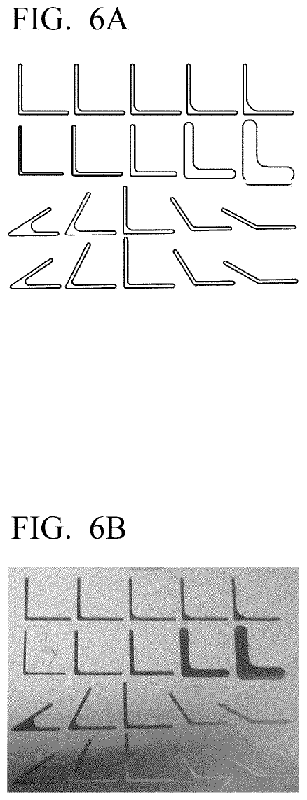

FIGS. 6A and 6B show 20 examples of various bent portions. FIG. 6A is a plan view showing configurations of CAD-designed bent portions (including two linear portions forming each bent portion), and FIG. 6B is a photograph of samples of the bent portions (including two linear portions forming each bent portion) actually produced corresponding to the CAD design. The view of the 20 bent portions shown in FIG. 6A and the 20 bent portion samples shown in FIG. 6B were arranged to correspond to each other.

All of the 20 bent portions shown in FIGS. 6A and 6B have a structure including a recessed triangular portion on the inner contour side and an arcuate portion on the outer contour side.

The samples were produced under the same production conditions as those in Experimental Example 3 described below.

The five bent portions shown in the uppermost row of FIGS. 6A and 6B have the same line width of two linear portions forming each bent portion and the same angle (90°) between the two linear portions, but the radius of curvature R1 of an arc of an arc-shaped bottom edge of each recessed triangular portion increases as the bent portions are positioned further to the right.

The five bent portions shown in the row below the uppermost row in FIGS. 6A and 6B have the same angle (90°) between two linear portions forming each bent portion and the same radius of curvature R1 of an arc of an arc-shaped bottom edge of each recessed triangular portion, but the line width of the two linear portions forming each bent portion increases as the bent portions are positioned further to the right.

The five bent portions shown in the row above the lowermost row in FIGS. 6A and 6B have the same line width of two linear portions forming each bent portion, but differ in the angle between the two linear portions. Accordingly, the size of the radius of curvature R1 of an arc of an arc-shaped bottom edge of each recessed triangular portion also differs. In particular, for the three bent portions on the right side, the radius of curvature R1 increases as the bent portions are positioned further to the right.

The five bent portions shown in the lowermost row of FIGS. 6A and 6B are similar to the five bent portions shown in the row above, but differ from the bent portions shown in the row above in that the three bent portions on the right side have the same radius of curvature R1.

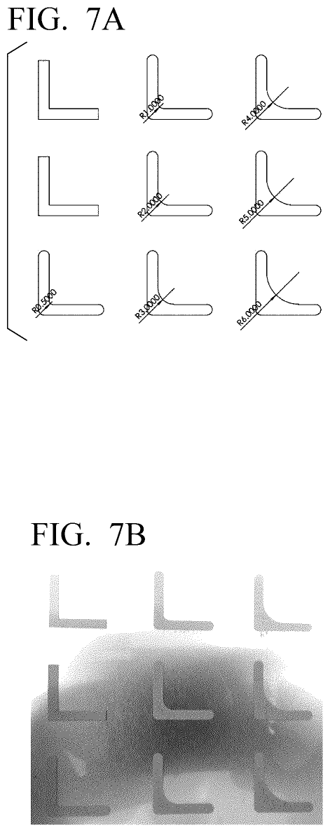

FIGS. 7A and 7B show results obtained to confirm production accuracy of the stretchable wirings, particularly the production accuracy in the vicinity of the bent portions. FIG. 7A is a plan view showing configurations of CAD-designed bent portions (including two linear portions forming each bent portion), and FIG. 7B is a photograph of samples of the bent portions (including two linear portions forming each bent portion) actually produced corresponding to the CAD design. The view of the nine bent portions shown in FIG. 7A and the nine bent portion samples shown in FIG. 7B were arranged to correspond to each other.

Of the three samples shown in each left column of FIGS. 7A and 7B, the upper two samples are based on exactly the same design. As shown in FIG. 7B, it can be seen that the samples were produced with high accuracy.

In addition, the lowermost sample of the three shown in each left column has, compared to the two upper samples, a recessed triangular portion on the inner contour side with a radius of curvature R1 of an arc of an arc-shaped bottom edge of 5 mm, and an arcuate portion on the outer contour side with an arc (having a central angle of less than 180°) R2 of 1 mm. As shown in FIG. 7B, it can be seen that the samples were produced with high accuracy.

The three samples shown in the center column of FIGS. 7A and 7B and the three samples shown in the right column have in common that an arc R2 of an arcuate portion positioned on the outer contour side is 1 mm. However, they differ in the size of the radius of curvature R1 of an arc of an arc-shaped bottom edge of a recessed triangular portion positioned on the inner contour side. R1 is 1 mm, 2 mm, and 3 mm for the three samples shown in the center column in order from the top, and 4 mm, 5 mm, and 6 mm for the three samples shown in the right column in order from the top. As shown in FIG. 7B, it can be seen that the samples were produced with high accuracy.

As for the material of the stretchable wiring 20, it is preferable that it have high conductivity and high stretchability, and that its change in conductivity during stretching and contracting be minimal.

The stretchable wiring 20 can contain a stretchable resin and conductive filler.

The stretchable resin is not particularly limited, and a well-known stretchable resin can be used as the stretchable resin. Examples thereof include epoxy resins, urethane resins, urea resins, polyurethane urea resins, methacrylic acid resins, polyacrylic resins, silicone resins, diene resins, polyester resins, polyether resins, polyamide resins, polystyrene resins, and polyimide resins.

As the stretchable resin, the same resin as that used for the stretchable insulating substrate 10 may be used.

The conductive filler is not particularly limited, and any well-known conductive filler can be used. Examples thereof include a silver (Ag) powder, carbon (C), a copper (Cu) powder, a palladium (Pd) powder, a gold (Au) powder, and a platinum (Pt) powder. Among these, a silver powder or an alloy powder mainly composed of silver is preferable because of its low resistance. Here, the alloy powder mainly composed of silver means that more than 50% of the powder is silver, and the percentage of silver is preferably 70% or more, more preferably 80% or more, and still more preferably 90% or more.

As conductive filler, those appropriately produced may be used, or commercially available products may be used.

The conductive filler preferably contains a flake-shaped powder. Here, the term “flake-shaped powder” in the present specification refers to a powder (metal powder) with a thickness of 1/10 or less of the maximum particle diameter. Here, the maximum particle diameter of the flake-shaped powder is defined as follows. Each powder particle has different end-to-end lengths depending on directions in a plan view, and the longest of these lengths is taken as a maximum particle diameter. The maximum particle diameter can be determined through optical microscopic observation, scanning electron microscope (SEM) observation (for example, 5000× field of view), or the like. This is because when conductive filler is flake-shaped, it has top and bottom surfaces that spread in the surface direction, and therefore, the percentage of surface contact between conductive filler particles is increased, leading to high conductivity (low resistivity). In addition, as flake-shaped conductive filler, one appropriately produced may be used, or a commercially available product may be used. Flake-shaped conductive filler can be produced, for example, by producing a thin film of a desired metal and then finely pulverizing the thin film. Since flake-shaped conductive filler is obtained by finely pulverizing thin films through the production method, individual crushed metal pieces are also flattened. The thickness with respect to the particle diameter (that is, the degree of flattening) can be adjusted by adjusting the thickness of the thin films and the degree of fine pulverization.

The percentage of a flake-shaped powder in the metal powder is preferably 2.5 wt % or more, more preferably 5 wt % or more, and still more preferably 7.5 wt % or more. In addition, the percentage of the flake-shaped powder in the metal powder is preferably 50 wt % or less, more preferably 40 wt % or less, still more preferably 30 wt % or less, and still more preferably 25 wt % or less.

From the viewpoint of high conductivity (low resistivity), a higher percentage of the flake-shaped powder in the metal powder is preferable. However, if the percentage thereof is too high, the stretchability will decrease and the elongation at break will decrease. The degree of freedom of movement of the metal powder is necessary for smooth stretching and contracting of the stretchable wiring, but when the percentage of the flake-shaped powder exceeds 50 wt %, it is thought to be due to the fact that the flake shape itself has a high resistance to movement.

The average maximum particle diameter of the flake-shaped powder is preferably 3 μm to 10 μm.

This is because if the average maximum particle diameter is 3 μm or more, sufficiently high conductivity (low resistivity) due to the effect of surface contact between metal powder particles can be obtained, and if the average maximum particle diameter is 10 μm or less, sufficient stretchability will decrease and the elongation at break will decrease.

The resin used in the stretchable wiring 20 is preferably soluble in any one or more kinds of solvents selected from diethylene glycol monobutyl ether, diethylene glycol monobutyl ether acetate (BCA), diethylene glycol monoethyl ether acetate, and «-terpineol.

Among the above-described resins, urethane resins that can be solidified without undergoing a curing reaction are preferable. In addition, since urethane resins have excellent stretchability, stretchable electrodes having stretchability and conductivity can be produced. This is because, with resins that require a curing reaction, if the curing reaction does not proceed uniformly, variations in composition and degree of curing may occur in resin sheets, resulting in resins that do not have desired stretchability, strength, and aging degradation resistance characteristics.

In addition, when a urethane resin is used, it is preferable that the resin component have a siloxane bond. This is because in this case, the resin composition has moderate water repellency, which inhibits hydrolysis of urethane bonds.

The stretchable wiring 20 preferably has an elongation at break of 20% or more. The elongation at break is more preferably 50% or more, still more preferably 100% or more, and most preferably 150% or more. The definition of “elongation at break” is the same as that described above.

The elongation at break of the stretchable wiring material can be increased by increasing the percentage of the resin in the stretchable wiring material, but the increase in percentage of the resin leads to an increase in resistivity. Therefore, the elongation at break is adjusted as appropriate by adjusting the percentage of the resin according to the elongation at break and resistivity required for a stretchable device in which the stretchable wiring material is used.

The thickness of the stretchable wiring 20 is not limited, but as a guideline, it can be, for example, 3 to 50 μm.

As an example of the stretchable wiring 20, it is possible to use one that contains a resin and a metal powder, in which the elongation at break is 130% or more, the resistivity (ρ₀) before stretching and contracting is 2×10⁻² [Ωcm] or less, the metal powder includes a flake-shaped powder, and the percentage of the resin is 8 wt % to 20 wt %.

As another example of the stretchable wiring 20, it is possible to use one that contains a resin and a metal powder, in which the elongation at break is 130% or more, the ratio (ρ₅₀/ρ₀) of a resistivity (ρ₅₀) at 50% elongation to a resistivity (ρ₀) before stretching and contracting is 7 or less, the metal powder includes a flake-shaped powder, and the percentage of the resin is 8 wt % to 20 wt %. In this case, one may be used in which the ratio (ρ₁₀₀/ρ₅₀) of a resistivity (ρ₁₀₀) at 100% elongation to a resistivity (ρ₅₀) at 50% elongation is 8 or less.

As another example of the stretchable wiring 20, it is possible to use one that contains a resin and a metal powder, in which the elongation at break is 130% or more, the rate of change of the ratio (ρ₁₀₀/ρ₅₀) of a resistivity (ρ₁₀₀) at 100% elongation to a resistivity (ρ₅₀) at 50% elongation with respect to the ratio (ρ₅₀/ρ₀) of a resistivity (ρ₅₀) at 50% elongation to a resistivity (ρ₀) before stretching and contracting is 140% or less, the metal powder includes a flake-shaped powder, and the percentage of the resin is 8 wt % to 20 wt %.

The resistivity before stretching and contracting is 2×10⁻² [Ωcm] or less. The resistivity thereof is preferably 7×10⁻³ [Ωcm] or less, more preferably 6×10⁻³ [Ωcm] or less, and still more preferably 4×10⁻³ [Ωcm] or less.

The resistivity before stretching and contracting of the stretchable wiring can be decreased by increasing the percentage of the metal powder in the stretchable wiring, but the decrease in percentage of the resin in accordance with the increase in percentage of the metal powder leads to a decrease in elongation at break. Therefore, the resistivity before stretching and contracting is adjusted as appropriate by adjusting the percentage of the metal powder according to the elongation at break and resistivity required for a stretchable device in which the stretchable wiring is used.

### <Use>

The stretchable wiring board according to the present embodiment can be used in products in which wiring boards have been used conventionally, but can also be suitably used in products in which high stretchability is required.

### <Method for Producing Stretchable Wiring Board>

Hereinafter, specific examples of resin compositions that are preferable to produce the resin contained in the stretchable insulating substrate 10 and the stretchable wiring 20 constituting the stretchable wiring board according to the present embodiment will be given to explain the production method and formation method of each constituent element.

Specific examples thereof include a resin composition containing a resin component (in the present specification, sometimes referred to as “resin component (II)”) having a urethane bond and a group represented by General Formulae (11), (21), or (31) below.

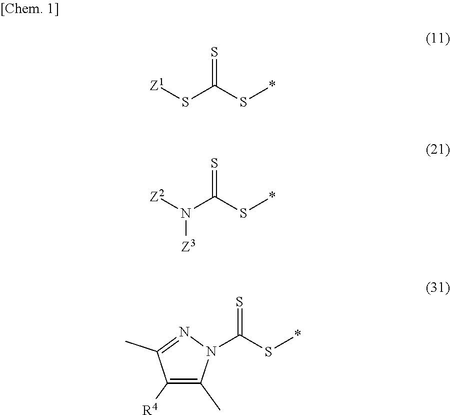

(In the formula, Z1 is an alkyl group, and one or more hydrogen atoms in the alkyl group may be substituted with a cyano group, a carboxy group, or a methoxycarbonyl group, and two or more of the substituents may be the same as or different from each other. Z2 is an alkyl group. Z3 is an aryl group. R4 is a hydrogen atom or a halogen atom. A bond marked with a sign * is formed at a bonding destination in the group represented by General Formulae (11), (21), or (31) above.)

The resin component (II) contained in this resin composition is highly flexible because it has a urethane bond.

In addition, the resin component (II) is obtained through a polymerization reaction using a resin having a urethane bond and a polymerizable unsaturated bond and a RAFT agent for performing reversible addition fragmentation chain transfer polymerization (abbreviated as “RAFT polymerization” in the present specification) from which the group represented by General Formulae (11), (21), or (31) above is derived. By conducting the polymerization reaction in this way, gelation of the resin during polymerization in the process of forming a cross-linked structure is avoided, and resin components with the desired degree of polymerization and cross-linked state are obtained. In other words, the resin component (II) having the group represented by General Formulae (11), (21), or (31) above has a small variation in terms of the degree of polymerization and the cross-linked state.

In addition, the resin component (II) may have a siloxane bond, in which case the resin composition has moderate water repellency, which inhibits hydrolysis of urethane bonds in the resin component (II). Such a resin component (II) is obtained through a further polymerization reaction using a resin having a siloxane bond and a polymerizable unsaturated bond.

The method for producing the resin component (II) in which the RAFT polymerization is performed will be described separately in detail.

The resin having a urethane bond and a polymerizable unsaturated bond used in the production of the resin component (II) is an oligomer and may be referred to as “resin (a).”

In addition, the resin having a siloxane bond and a polymerizable unsaturated bond used in the production of the resin component (II) is an oligomer and may be referred to as “resin (b)” in the present embodiment.

The resin component (II) is a polymer formed through polymerization of resins (a) at their polymerizable unsaturated bonds. When the resin (b) is used, the resin component (II) is a polymer formed through polymerization of the resin (a) and the resin (b) at their polymerizable unsaturated bonds.

When the resin (b) is used, the resin component (II) preferably has both urethane and siloxane bonds in one molecule thereof.

The resin (a) is not particularly limited as long as it has a urethane bond and a polymerizable unsaturated bond.

Examples of the resin (a) includes those having a (meth)acryloyl group as a group having a urethane bond and a polymerizable unsaturated bond, and more specific examples thereof include urethane (meth)acrylate.

In the present specification, “(meth)acrylate” is a concept that encompasses both “acrylate” and “methacrylate.” The same applies to terms similar to (meth)acrylate. For example, “(meth)acryloyl group” is a concept that encompasses both “acryloyl group” and “methacryloyl group.”

The resin (b) is not particularly limited as long as it has a siloxane bond and a polymerizable unsaturated bond.

Examples of the resin (b) include various well-known silicone resins having a (meth)acryloyl group as a group having a polymerizable unsaturated bond, and more specific examples thereof include a modified polydialkylsiloxane in which a (meth)acryloyl group is bound to a single terminal or both terminals of polydialkylsiloxane such as polydimethylsiloxane.

The resin component (II) has high solubility in solvents due to its composition. Therefore, the resin composition containing the resin component (II) also has high solubility in solvents.

Such a resin composition having high solubility can easily form a resin composition layer through printing on an object to be applied, for example, through various printing methods. This resin composition layer can then be solidified through drying, without curing, to produce a layer (resin layer, resin sheet) similar to the resin sheets. Such a technique is suitable for forming electrodes or wiring using the resin composition containing conductive components.

Such a resin composition having high solubility is used to form a stretchable resin sheet, and a stretchable device composed of this resin sheet has the great advantage of suppressing damage during its stretching and contracting.

Factors that can cause damage to normal stretchable devices during stretching and contracting, from the viewpoint of materials, include (i) interface delamination and structural defects such as voids caused by contraction due to heat or curing reactions, (ii) uneven hardness caused by uneven composition, and (iii) degradation of materials over time caused by light exposure, oxidation, and the like.

Therefore, structural defects such as voids, and interface delamination, uneven composition, and degradation of materials over time can be suppressed, thereby preventing damage to the stretchable devices during stretching and contracting.

When the stretchable insulating substrate 10 is used as a stretchable board, its processing is commonly performed by molding by thermal melting and cross-linking by thermosetting or photocuring reactions. However, there is a concern that the reliability of the stretchable devices will be lowered if even micromachining is considered due to the reasons (i) to (iii). In contrast, for example, if there is a resin that can be molded only through applying and drying a resin composition in response to a lamination process, it is expected that favorable results can be obtained.

### <Method for Producing Stretchable Insulating Substrate>

For the stretchable insulating substrate 10, the resin composition of the above-described specific example can be solidified through drying to obtain a resin sheet-like stretchable insulating substrate (hereinafter, sometimes referred to as a “resin sheet”). When a stretchable insulating substrate is used as a stretchable board, a plurality of resin sheets may be stacked to produce a stretchable insulating substrate.

The resin sheet has favorable stretchability because it contains the resin component (II) as its main component. When the resin (b) is used, the resin sheet further has moderate water repellency, which suppresses degradation over time caused by hydrolysis. The resin sheet with such characteristics is particularly suitable for constructing various types of stretchable devices including wearable devices.

The resin sheet can be formed simply by solidifying the resin composition through drying, as described above, without any curing reaction. Therefore, it does not have the defects associated with performing a curing reaction.

For example, a photocuring reaction is significantly difficult to uniformly cure materials that do not transmit ultraviolet light. For example, when the periphery of a mounted device or electronic components is irradiated with ultraviolet light, the degree of curing may vary in some areas in a photocurable resin sheet due to variations in ultraviolet light transmission, and the resin sheet is easily damaged in areas with low cross-linking density. In addition, non-cross-linked areas are easily degraded by oxidation.

On the other hand, a thermosetting reaction easily causes contraction differences in the resin sheet due to heat distribution during curing. When such contraction differences occur, different constituent materials among devices, sealants, and the like are easily delaminated at these interfaces. In addition, if areas with different degrees of curing are created in the resin sheet due to heat distribution, the sheet will be easily degraded due to repeated stretching and contracting.

Furthermore, in both cases of photocuring and thermosetting reactions, it is difficult for the reactions to progress uniformly in the resin sheet. In such cases, variations in composition and degree of curing occur in the resin sheet, and the cured resin sheet does not have desired stretchability and strength. In addition, because a curing agent is incorporated, degradation over time due to heat or light easily occurs.

In contrast, the resin sheet obtained by solidifying the resin composition of the specific example through drying does not have such defects.

The resin sheet can be produced without a curing reaction by, for example, applying the resin composition to a desired section and solidifying it through drying.

The resin composition can be applied, for example, through well-known methods using various coaters, wire bars, or the like, or through various printing methods including inkjet printing methods.

During the production of the resin sheet, the drying temperature of the resin composition is preferably 25° C. to 150° C. and more preferably 25° C. to 120° C. When the drying temperature is 25° C. or higher, it is possible to more efficiently produce a resin sheet. When the drying temperature is 150° C. or lower, the drying temperature is suppressed from becoming excessively high, deformation of a release sheet and damage to the resin sheet are less likely to occur, and deterioration of the resin sheet is suppressed.

The drying time of the resin composition during production of the resin sheet may be appropriately set according to the drying temperature, and is preferably 10 to 120 minutes and more preferably 30 to 90 minutes. When the drying time is within these ranges, resin sheets with favorable characteristics can be efficiently produced.

Completion of solidification of the resin composition through drying (formation of the resin sheet) can be confirmed, for example, by the fact that no clear change in mass of the resin composition being subjected to drying can be observed.

The elongation of the stretchable insulating substrate can be appropriately set according to the elongation required for the intended product. For example, it can be appropriately set to a value of 20% or more. The elongation can be adjusted, for example, by increasing the amount of stretchable resin to increase the elongation. In addition, the elongation can be adjusted by increasing the mol % of bonds with high elongation in the resin. For example, the elongation of the stretchable insulating substrate 10 can be increased by increasing the percentage of urethane bonds in the resin.

### <Method for Forming Stretchable Wiring>

The stretchable wiring can be formed, for example, through main steps: a (1) stretchable wiring paste preparation step; a (2) stretchable wiring paste application step; and a (3) drying and solidifying step.

In other words, in the (1) stretchable wiring paste preparation step, a metal powder is incorporated into a resin composition containing the above-described resin and solvent to prepare a stretchable wiring paste. Next, in (2) the stretchable wiring paste application step, the stretchable wiring paste is applied to one surface of a stretchable insulating substrate (for example, a PET film) in a predetermined pattern (for example, a pattern designed by CAD). Thereafter, in the (3) drying and solidifying step, stretchable wiring can be formed by removing the solvent and drying and solidifying the stretchable wiring paste.

When the stretchable wiring 20 is formed using the resin composition of the above-described specific example, the following process can be carried out.

First, conductive filler is incorporated into the resin composition of the above-described specific example to prepare a stretchable wiring paste. Next, the stretchable wiring paste is applied to the stretchable insulating substrate 10 in a predetermined pattern (for example, a pattern designed by CAD), and then the solvent is removed and the stretchable wiring paste is dried and solidified to obtain stretchable wiring. By applying the stretchable wiring paste multiple times, the thickness of the stretchable wiring can be increased. In addition, by applying the stretchable wiring paste to the section constituting the stretchable wiring, it is also possible to form the stretchable wiring by changing the stretchable wiring material for each section or by changing the composition ratio even within the same stretchable wiring material.

The stretchable wiring has favorable stretchability because it contains the resin component (II) as its main component. When the resin (b) is used, the stretchable wiring further has moderate water repellency, which suppresses degradation over time caused by hydrolysis. The stretchable wiring with such characteristics is particularly suitable for constructing various types of stretchable devices including wearable devices.

The stretchable wiring can be formed simply by solidifying the resin composition through drying, as described above, without any curing reaction. Therefore, it does not have the defects associated with performing a curing reaction.

For example, a photocuring reaction is significantly difficult to uniformly cure materials that do not transmit ultraviolet light. For example, when the periphery of a mounted device or electronic components is irradiated with ultraviolet light, the degree of curing may vary in some areas in a photocurable wiring pattern due to variations in ultraviolet light transmission, and the wiring pattern is easily damaged in areas with low cross-linking density. In addition, non-cross-linked areas are easily degraded by oxidation.

On the other hand, a thermosetting reaction easily causes contraction differences in the wiring pattern due to heat distribution during curing. When such contraction differences occur, different constituent materials among devices, sealants, and the like are easily delaminated at these interfaces. In addition, if areas with different degrees of curing are created in the wiring pattern due to heat distribution, the pattern will be easily degraded due to repeated stretching and contracting.

Furthermore, in both cases of photocuring and thermosetting reactions, it is difficult for the reactions to progress uniformly in the wiring pattern. In such cases, variations in composition and degree of curing occur in the wiring pattern, and the cured wiring pattern does not have desired stretchability and strength. In addition, because a curing agent is incorporated, degradation over time due to heat or light easily occurs.

In contrast, the wiring stretchable wiring obtained by solidifying the stretchable wiring paste containing the resin composition of the above-described specific example through drying does not have such defects.

The stretchable wiring can be formed without a curing reaction by, for example, applying the stretchable wiring paste to a desired site and solidifying it through drying.

The stretchable wiring paste can be applied, for example, through well-known methods using various coaters, wire bars, or the like, or through various printing methods including inkjet printing methods.

During the production of the stretchable wiring, the drying temperature of the stretchable wiring paste is preferably 25° C. to 150° C. and more preferably 25° C. to 120° C. When the drying temperature is 25° C. or higher, it is possible to more efficiently fabricate the stretchable wiring. When the drying temperature is 150° C. or lower, the drying temperature is suppressed from becoming excessively high, deformation of a release sheet and damage to the stretchable wiring are less likely to occur, and deterioration of the stretchable wiring is suppressed.

The drying time of the stretchable wiring paste during formation of the stretchable wiring may be appropriately set according to the drying temperature, and is preferably 10 to 120 minutes and more preferably 30 to 90 minutes. When the drying time is within these ranges, stretchable wiring with favorable characteristics can be efficiently fabricated.

Completion of solidification of the stretchable wiring paste through drying (formation of the stretchable wiring) can be confirmed, for example, by the fact that no clear change in mass of the resin composition being subjected to drying can be observed.

In the stretchable wiring, resistivity is as important as the elongation. Increasing the percentage of resin in the stretchable wiring increases the elongation but also increases the resistivity. On the other hand, increasing the percentage of conductive filler reduces the resistivity but also reduces the elongation. Therefore, the percentage of the resin and the conductive filler mixed in the stretchable wiring paste is adjusted according to the elongation required for the intended product.

### EXAMPLES

Hereinafter, examples of manufacturing a stretchable wiring board according to the embodiment will be shown using specific materials.

### <Examples of Raw Materials for Resin Composition>

Raw materials that can be used to produce a resin composition are shown below.

### Resin (a)

(a)-1: Urethane acrylate oligomer (product name: UN-5500, manufactured by Negami Chemical Industrial Co., Ltd.)

### Resin (b)

(b)-1: Methacrylate-modified polydimethylsiloxane modified with a methacryloyl group at a single terminal (product name: Silaplane (registered trademark) FM-0721, manufactured by JNC Corporation)

### Polymerization Initiator (c)

(c)-1: Dimethyl 2,2′-azobis(2-methylpropionate), azo polymerization initiator (product name: V601, manufactured by FUJIFILM Wako Pure Chemical Corporation)

### RAFT Agent

(1)-1: RAFT agent represented by Formula (1)-1 below (manufactured by FUJIFILM Wako Pure Chemical Corporation)
(3)-1: RAFT agent represented by Formula (3)-1 below (manufactured by FUJIFILM Wako Pure Chemical Corporation)

### Other Polymerizable Components

MMA: Methyl methacrylate

### Solvent

BCA: Butyl carbitol acetate

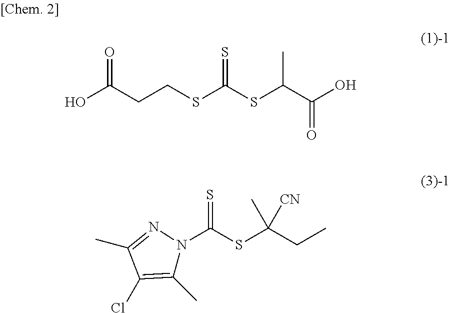 [SMILES: CC(SC(=S)SCCC(=O)O)C(=O)O ; CCC(C)(C#N)SC(=S)n1nc(C)c(Cl)c1C]

### <Production Example of Resin Composition>

A resin (a)-1 (100 parts by mass), a polymerization initiator (c)-1 (0.8 parts by mass), a RAFT agent (1)-1 (0.245 parts by mass), and BCA were weighed out in a flask and mixed together using a stirrer at normal temperature to obtain a raw material mixture.

The formulation amounts of resin (b), polymerization initiator (c), and RAFT agent are determined based on 100 parts by mass of the resin (a).

In addition, BCA, which is a solvent, is mixed so that 100 parts by mass of the resin (a) becomes 15 mass % of the raw material mixture.

The sealed flask is then degassed under vacuum.

Next, the raw material mixture is dissolved using an oil bath in a nitrogen atmosphere, and the temperature is subsequently raised while stirring. A polymerization reaction is carried out at 90° C. for 20 minutes to produce a resin component (II), along with a resin composition containing this resin component (II).

### <Production Example of Stretchable Insulating Substrate>

The resin composition obtained above was applied to a release film using a spray coater and dried at 115° C. for 60 minutes to produce a resin sheet (test resin sheet, thickness of 80 μm), which can then be used as a stretchable insulating substrate.

### <Example of Forming Stretchable Wiring>

Raw materials for the stretchable wiring paste are the same as those for the resin composition prepared when producing the stretchable insulating substrate described above, except that a silver powder having a particle size of 0.5 μm to 5.0 μm is added and the amount of resin is adjusted.

Subsequently, the stretchable wiring paste is applied to the stretchable insulating substrate in a predetermined pattern, and then stretchable wiring can be formed by removing a solvent and drying and solidifying the stretchable wiring paste.

### <Evaluation of Change in Conductivity of Stretchable Wiring During Stretching and Contracting>

### Experimental Example 1

A sample of stretchable wiring of Experimental Example 1 was produced as follows.

The above-described resin (a)-1, the above-described polymerization initiator (c)-1, the above-described RAFT agent (1)-1, a silver powder (percentage of a flake-shaped powder: 12.5 [wt %], average maximum particle diameter: 3 μm), and BCA were weighed out in a flask and mixed together using a stirrer at normal temperature to obtain a stretchable wiring paste.

The formulation amounts of resin (b), polymerization initiator (c), and RAFT agent were determined so that the percentage of urethane bonds in the resins in the resulting stretchable wiring was 20 wt % based on 100 parts by mass of the resin (a). In addition, the formulation amount of silver powder was determined so that the percentage of the resins in the resulting stretchable wiring was 5 wt %. In other words, the formulation amount of silver powder was determined so that the ratio of the resins to the silver powder was 8 wt %: 92 wt %.

Subsequently, sheet-like samples of stretchable wirings were produced through the above-described method, and an elongation at break, a resistivity (ρ₀) before stretching and contracting, a resistivity (ρ₅₀) at 50% elongation, and a resistivity (ρ₁₀₀) at 100% elongation were measured.

The resistance value and resistivity were measured as follows.

First, a sheet-like sample of stretchable wiring is prepared through the method described above.

The resistivity before stretching and contracting can be measured as follows. Similarly to the measurement of an elongation at break, six strip-like measurement samples of 10 mm wide and 30 mm long are cut out from each sheet-like sample of the stretchable wiring. A metal substrate is sandwiched between grip portions at the top and bottom of a measuring instrument, and each measurement sample is fixed with double-sided tape so that the measurement site is 10 mm wide and 10 mm long. The resistance value of each measurement sample is measured in this condition. An average value thereof is taken as a resistance value R₀ before stretching and contracting. The resistance value for each elongation is measured each time during stretching while stretching the sample by moving the metal substrate by 1 mm each, and an average value of the six samples is taken as a resistance value R during stretching thereof.

Subsequently, the thickness of each sheet-like sample of the stretchable wiring is then measured as follows. Each sheet-like sample of the stretchable wiring is punched out in a circular shape. Subsequently, the sample is placed on a flat table, and a rectangular PET film with one side larger than the diameter of the circular sample is placed on the sample. The thickness of four corners of a rectangular PET film is measured by, for example, Digimicro ZC-101 (manufactured by Nikon Corporation), and an average thereof is taken as a thickness of the PET film. Next, the combined thickness of the sample and the PET film is measured at five points (top, bottom, left, right, and center), and the thickness of the PET film is subtracted from the average thickness to calculate the thickness t of the sample.

Next, the resistivity ρ₀ (=R₀×(cross-sectional area/length)) is calculated from the above-described resistance value R₀ before stretching and contracting and the thickness t, width, and length of the sheet-like sample of the stretchable wiring.

In addition, similarly, the resistivity ρ (=R×(cross-sectional area/length)) at each elongation is also calculated from the resistance value at each elongation and the thickness t, width, and length of the sheet-like sample of the stretchable wiring.

The obtained results are shown in Table 1.

TABLE 1

| | | | Metal | | | | | |
|---|---|---|---|---|---|---|---|---|
| | Resin | | powder | | Resistivity | | | |
| | Percentage | Percentage | Percentage | | (Rdc) before | | | |
| | of resin in | of urethane | of flake- | | stretching | | | Rate of change |
| | wiring | bond in | shaped | | and | | | of (ρ₁₀₀/ρ₅₀) |
| | material | resin | powder | Elongation | contracting | | | with respect to |
| | [wt %] | [t %] | [wt %] | at break [%] | [Ω cm] | ρ₅₀/ρ₀ | ρ₁₀₀/ρ₅₀ | (ρ₅₀/ρ₀) (%) |
| Comparative | 6 | 20 | 12.5 | 5.3 | 8.60*10\hat{ }(−3) | — | — | — |
| Example 1 | | | | | | | | |
| Example 1 | 8 | 20 | 12.5 | 130.0 | 2.81*10\hat{ }(−3) | 5.3 | 8.0 | 51% |
| Example 2 | 10 | 20 | 12.5 | 165.3 | 4.28*10\hat{ }(−3) | 4.0 | 4.5 | 13% |
| Example 3 | 15 | 20 | 12.5 | 322.1 | 4.64*10\hat{ }(−3) | 5.3 | 5.4 | 0% |
| Example 4 | 18 | 20 | 12.5 | 370.8 | 3.00*10\hat{ }(−3) | 2.9 | 5.2 | 82% |
| Example 5 | 20 | 20 | 12.5 | 414.9 | 1.53*10\hat{ }(−2) | 1.7 | 4.0 | 133% |
| Comparative | 22 | 20 | 12.5 | 482 | 2.89*10\hat{ }(−1) | 0.012 | 4.4 | 36030% |
| Example 2 | | | | | | | | |
| Comparative | 15 | 0 | 12.5 | 6.0 | 3.59*10\hat{ }(−1) | — | — | — |
| Example 3 | | | | | | | | |
| Comparative | 15 | 10 | 12.5 | 7.0 | 1.13*10\hat{ }(−2) | — | — | — |
| Example 4 | | | | | | | | |
| Comparative | 15 | 15 | 12.5 | 37.4 | 6.48*10\hat{ }(−3) | — | — | — |
| Example 5 | | | | | | | | |
| Example 6 | 15 | 17.5 | 12.5 | 172.3 | 7.34*10\hat{ }(−3) | 3.3 | 4.1 | 25% |
| Example 3 | 15 | 20 | 12.5 | 322.1 | 4.64*10\hat{ }(−3) | 5.3 | 5.4 | 0% |
| Example 7 | 15 | 22 | 12.5 | 297.1 | 6.61*10\hat{ }(−3) | 5.0 | 5.35 | 7% |
| Example 8 | 15 | 25 | 12.5 | 245.5 | 4.75*10\hat{ }(−3) | 2.8 | 4.9 | 75% |
| Example 9 | 15 | 30 | 12.5 | 130.4 | 3.29*10\hat{ }(−3) | 5.0 | — | — |
| Comparative | 15 | 30 | 0 | 47.2 | 4.71*10\hat{ }(−1) | — | — | — |
| Example 6 | | | | | | | | |
| Comparative | 15 | 30 | 12.5 | 8.9 | 1.93*10\hat{ }(−3) | — | — | — |
| Example 7 | | | | | | | | |
| Example 10 | 15 | 20 | 2.5 | 322.1 | 4.72*10\hat{ }(−3) | 3.3 | 4.2 | 27% |
| Example 11 | 15 | 20 | 7.5 | 275.9 | 4.77*10\hat{ }(−3) | 2.8 | 3.9 | 42% |
| Example 3 | 15 | 20 | 12.5 | 322.1 | 4.64*10\hat{ }(−3) | 5.3 | 5.4 | 0% |
| Example 12 | 15 | 20 | 30 | 300 | 4.76*10\hat{ }(−3) | 4.0 | 6.9 | 73% |
| Example 13 | 15 | 20 | 40 | 230.5 | 5.62*10\hat{ }(−3) | 2.2 | 5.10 | 131% |
| Example 14 | 15 | 20 | 50 | 169.3 | 2.66*10\hat{ }(−3) | 51 | — | — |

### Experimental Examples 2 to 5 and Comparative Examples 1 and 2

For Experimental Examples 2 to 5 and Comparative Examples 1 and 2, sheet-like samples of stretchable wirings were produced in the same manner as in Experimental Example 1 except that the formulation amount of silver powder was adjusted so that the percentage of resins in each resulting stretchable wiring was 10 wt %, 15 wt %, 18 wt %, 20 wt %, 6 wt %, and 22 wt %. The same characteristics were measured on the resulting samples. The results are shown in Table 1.

### Experimental Examples 6 to 9 and Comparative Examples 3 to 5

For all of Experimental Examples 6 to 9 and Comparative Examples 3 to 5, sheet-like samples of stretchable wirings were produced in the same manner as in Experimental Example 1 except that the formulation amount was adjusted so that the percentage of resins in each resulting stretchable wiring was 15 wt % and the percentage of urethane bonds in the resins in each resulting stretchable wiring was 17.5 wt %, 20 wt %, 22 wt %, 25 wt %, 30 wt %, 0 wt %, 10 wt %, and 15 wt %. The same characteristics were measured on the resulting samples. The results are shown in Table 1.

### Comparative Examples 6 and 7

Comparative Examples 6 and 7 are those in which each stretchable wiring paste was applied and then subjected to a curing reaction instead of drying and solidifying. In Comparative Example 6, a stretchable wiring paste was obtained in the same manner as in Comparative Example 5 except that a silver powder did not have a flake shape. In Comparative Example 7, the same stretchable wiring paste as in Experimental Example 9 was used. The same characteristics were measured on the resulting samples. The results are shown in Table 1.

### Experimental Examples 10 to 14

For all of Experimental Examples 10 to 14, sheet-like samples of stretchable wirings were produced in the same manner as in Experimental Example 1 except that the percentage of resins in each resulting stretchable wiring was 15 wt %, the percentage of urethane bonds in the resins in each resulting stretchable wiring was 20 mol %, and a silver powder in which the percentage of each flake-shaped powder was 2.5 wt %, 7.5 wt %, 12.5 wt %, 30 wt %, 40 wt %, and 50 wt % was used.

The same characteristics were measured on the resulting samples. The results are shown in Table 1.

Findings obtained from the results of Table 1 will be shown. Values not included in Table 1 are those that could not be measured or were not measured.

Experimental Examples 1 to 6 and Comparative Examples 1 and 2 will be compared with each other. When the percentage of urethane bonds in resins and the percentage of a flake-shaped powder were fixed to the percentages shown in Table 1, the following findings were obtained.

When the percentage of resins in a wiring material was 8 wt % (resin: silver powder=8:92) or more, the elongation at break was 130% or more, and the higher the percentage of the resins, the higher the elongation at break was obtained. On the other hand, when the percentage of resins was 20 wt % or more, the resistivity before stretching and contracting was 1×10⁻² [Ωcm] or more. From the viewpoint of achieving both a higher elongation at break (150% or more) and a lower resistivity before stretching and contracting (5×10⁻³ [Ωcm] or less), the percentage of resins in a wiring material is preferably 10 wt % to 18 wt %.

In addition, when the percentage of resins was 20 wt % (resin: silver powder=20:80) (Experimental Example 5), the resistivity before stretching and contracting was 1.53×10⁻² [Ωcm] which was slightly high. However, reflecting its high elongation at break, the ratio (ρ₅₀/ρ₀) of a resistivity (ρ₅₀) at 50% elongation to a resistivity (ρ₀) before stretching and contracting was 1.7 which was a low rate of change and the ratio (ρ₁₀₀/ρ₅₀) of a resistivity (ρ₁₀₀) at 100% elongation to a resistivity (ρ₅₀) at 50% elongation was 4.0 which was a sufficiently low rate of change. From the viewpoint of achieving both the high elongation at break (150% or more) and low ratios (ρ₅₀/ρ₀) and (ρ₁₀₀/ρ₅₀), the percentage of resins in a wiring material is preferably 10 wt % to 20 wt %.

In addition, from the viewpoint of achieving both the high elongation at break (150% or more) and a low rate of change of the ratio (ρ₁₀₀/ρ₅₀) to the ratio (ρ₅₀/ρ₀), the percentage of resins in a wiring material is preferably 10 wt % to 15 wt %.

Furthermore, from the viewpoint of satisfying all of the high elongation at break (150% or more), the low resistivity before stretching and contracting, the low ratios (ρ₅₀/ρ₀) and (ρ₁₀₀/ρ₅₀), and the low rate of change of the ratio (ρ₁₀₀/ρ₅₀) to the ratio (ρ₅₀/ρ₀), the percentage of resins in a wiring material is preferably 10 wt % to 15 wt %.

Next, Experimental Examples 3, 6 to 9 and Comparative Examples 3 and 4 will be compared with each other. When the percentage of resins in a wiring material and the percentage of a flake-shaped powder were fixed to the percentages shown in Table 1, the following findings were obtained.

When the percentage of urethane bonds in resins was 15 wt % or less, the elongation at break was 40% or less. On the other hand, when the percentage of urethane bonds was 25 wt % (Experimental Example 8), the elongation at break was 245.5%, but when the percentage thereof was 30 wt % (Experimental Example 9), the elongation at break was 130.4%. From the viewpoint of a high elongation at break (150% or more), the percentage of urethane bonds in resins is preferably 17.5 wt % to 25 wt %. In addition, from the viewpoint of achieving both a higher elongation at break (150% or more) and a lower resistivity before stretching and contracting (7×10⁻³ [Ωcm] or less), the percentage of urethane bonds in resins is preferably 20 wt % to 25 wt %.

In addition, from the viewpoint of achieving both the high elongation at break (150% or more) and low ratios (ρ₅₀/ρ₀) and (ρ₁₀₀/ρ₅₀), the percentage of urethane bonds in resins is preferably 17.5 wt % to 25 wt %.

In addition, from the viewpoint of achieving both the high elongation at break (150% or more) and a low rate of change of the ratio (ρ₁₀₀/ρ₅₀) to the ratio (ρ₅₀/ρ₀), the percentage of urethane bonds in resins is preferably 17.5 wt % to 22 wt %.

Furthermore, from the viewpoint of satisfying all of the high elongation at break (150% or more), the low resistivity before stretching and contracting, the low ratios (ρ₅₀/ρ₀) and (ρ₁₀₀/ρ₅₀), and the low rate of change of the ratio (ρ₁₀₀/ρ₅₀) to the ratio (ρ₅₀/ρ₀), the percentage of urethane bonds in resins is preferably 17.5 wt % to 22 wt %.

In Comparative Examples 6 and 7, each stretchable wiring paste was applied and then subjected to a curing reaction instead of drying and solidifying. However, the resistivity before stretching and contracting in Comparative Example 6 in which a silver powder did not have a flake shape was about 5×10⁻¹ [Ωcm] which was considerably high, and the elongation at break in Comparative Example 7 of which the composition of the stretchable wiring paste itself was the same as that of Experimental Example 9 was 10% or less. Therefore, it was found that Comparative Examples 6 and 7 were not suitable for application to stretchable devices.

Next, Experimental Examples 3, 10 to 14 were compared with each other. When the percentage of resins in a wiring material and the percentage of urethane bonds in the resins were fixed to the percentages shown in Table 1, the following findings were obtained.

As the percentage of a flake-shaped powder in a silver powder was 40 wt % or 50 wt %, the elongation at break was negatively affected and gradually decreased. Furthermore, at 40 wt % (Experimental Example 13), the rate of change of the ratio (ρ₁₀₀/ρ₅₀) to the (ρ₅₀/ρ₀) increased to 130% or more, and at 50 wt % (Experimental Example 14), the ratio (ρ₅₀/ρ₀) was 51 times greater.

From a viewpoint, when the percentage of a flake-shaped powder in a silver powder is within a range of 2.5 wt % to 50 wt %, it is possible to achieve both a higher elongation at break (150% or more) and a lower resistivity before stretching and contracting 7×10⁻³ [Ωcm] or less).

From the viewpoint of achieving both the high elongation at break (150% or more) and low ratios (ρ₅₀/ρ₀) and (ρ₁₀₀/ρ₅₀), the percentage of a flake-shaped powder in a silver powder is preferably 2.5 wt % to 40 wt %.

In addition, from the viewpoint of achieving both the high elongation at break (150% or more) and a low rate of change of the ratio (ρ₁₀₀/ρ₅₀) to the ratio (ρ₅₀/ρ₀), the percentage of a flake-shaped powder in a silver powder is preferably 2.5 wt % to 12.5 wt %.

Furthermore, from the viewpoint of satisfying all of the high elongation at break (150% or more), the low resistivity before stretching and contracting, the low ratios (ρ₅₀/ρ₀) and (ρ₁₀₀/ρ₅₀), and the low rate of change of the ratio (ρ₁₀₀/ρ₅₀) to the ratio (ρ₅₀/ρ₀), the percentage of a flake-shaped powder in a silver powder is preferably 2.5 wt % to 12.5 wt %.

High flexibility is obtained by containing urethane bonds in resins. In addition, when resins contain either urethane bonds or siloxane bonds, both high stretchability and low resistivity can be achieved through an effect of improving dispersion and aggregation of a silver powder. Furthermore, when both the urethane bonds and the siloxane bonds are contained, a higher improvement effect is obtained.

### <Durability Evaluation of Structure of Stretchable Wiring>

The durability of a structure of stretchable wiring constituting the stretchable wiring board according to the present embodiment was evaluated. Specifically, a structure of stretchable wiring was designed using CAD, and a sample of a bent portion (including two linear portions forming the bent portion) was produced under the same production conditions as in Experimental Example 3, and the presence or absence of cracks after repeated stretching and contracting tests was evaluated. The sample of the bent portion produced had a recessed triangular portion on the inner contour and an arcuate portion on the outer contour as shown in FIG. 4 (refer to FIGS. 6 and 7).

### (Production of Samples)

As stretchable insulating substrates, 60 mm×65 mm square urethane films with a thickness of 100 μm were prepared. Next, a pattern of a bent portion structure of stretchable wiring designed by CAD was formed on each urethane film to produce samples.

The dimensions of the bent portion samples and the angles between linear portions (the angle between the linear portion 20Ad and the linear portion 20Ae in FIG. 4) are as follows.
Thickness: 10 μm, 20 μm, 30 μm
Line width D: 0.5 mm, 0.75 mm, 1.5 mm, 2 mm, 2.25 mm, 3 mm
Radius of curvature R1 of arc-shaped bottom edge of recessed triangular portion: 0 mm, 0.5 mm, 0.75 mm, 1.5 mm, 2.25 mm, 3 mm, 4 mm, 5 mm, 6 mm (0 mm is when there is no recessed triangular portion)
Radius of curvature R2 of arc of arcuate portion: 1 mm
Angle between linear portions: 30°, 60°, 90°, 120°, 150°

### (Repeated Stretching and Contracting Tests)

Next, the produced samples were subjected to a 1,000 cycle test using a tensile tester (Autograph (manufactured by Shimadzu Corporation)) with the elongation set to 50%, and then the presence or absence of cracks in each recessed triangular portion of the samples was visually observed using a magnifying glass.

### (Evaluation Results)

A plurality of samples having the same dimensions and angles were produced, and the crack occurrence percentage (%) was examined.

When there was no recessed triangular portion (R1=0 mm), the crack occurrence percentage was 100%.

When the angle between linear portions was 90° or less, the crack occurrence percentage was 50% or less, but when the angle therebetween was 120° or 150°, the crack occurrence percentage exceeded 60%.

For a case where the wiring thickness is 10 μm to 30 μm, the results of examining the crack occurrence percentage using L1=radius of curvature R1/line width D as a parameter are shown in Table 2.

TABLE 2

| R1/D | 0 | 0.25 | 0.5 | 1 | 1.5 | 2 | 2.5 | 3 |
|---|---|---|---|---|---|---|---|---|
| Crack | 100% | 50% | 17% | 17% | 17% | 17% | 50% | 50% |
| occurrence | | | | | | | | |
| percentage | | | | | | | | |

Based on the above results, it was found that the presence of a recessed triangular portion can reduce the crack occurrence percentage.

The angle between linear portions forming a bent portion is preferably 90° or less.

It was found that, when the wiring thickness is 10 μm to 30 μm, the crack occurrence percentage can be halved when the radius of curvature R1/line width D is 0.25 to 3. Furthermore, it was found that, when the radius of curvature R1/line width D is 0.5 to 2, the crack occurrence percentage can be significantly reduced.

### REFERENCE SIGNS LIST

10 Stretchable insulating substrate
20 Stretchable wiring
20A Linear portion
20B Bent portion
20Bd-1 Rectangular section
20Bd-2 Recessed triangular portion
100 Stretchable wiring board

1. A stretchable wiring board comprising:
a stretchable insulating substrate containing a resin; and
a stretchable wiring that contains a resin and is formed on a main surface of the stretchable insulating substrate,
wherein the stretchable wiring has a plurality of linear portions extending linearly in multiple different directions, and bent portions that connect the linear portions extending in the different directions, and
wherein the bent portions have a rectangular section and a recessed triangular portion which is positioned on an inner contour side of the inner contour and an outer contour constituting its outer shape and is surrounded by two slanted edges and a recessed arc-shaped bottom edge when viewed in plan view.

2. A stretchable wiring board comprising:
a stretchable insulating substrate containing a resin; and
a stretchable wiring that contains a resin and is formed on a main surface of the stretchable insulating substrate,
wherein the stretchable wiring has a plurality of linear portions extending linearly in multiple different directions, and bent portions that connect the linear portions extending in the different directions, and
wherein the bent portions have a rectangular section and an arcuate portion which is positioned on an outer contour side of an inner contour and the outer contour constituting its outer shape and is surrounded by an arc (having a central angle of less than 180°) and a chord connecting both end points of the arc when viewed in plan view.

3. The stretchable wiring board according to claim 1,
wherein the bent portions further have an arcuate portion which is positioned on the outer contour side and is surrounded by an arc (having a central angle of less than) 180° and a chord connecting both end points of the arc when viewed in plan view.

4. The stretchable wiring board according to claim 1,
wherein when the line width of two linear portions forming each of the bent portions is D and the radius of curvature of the recessed arc-shaped bottom edge is R1, the relational expression 0.5≤L1≤2 holds when L1=R1/D.

5. The stretchable wiring board according to claim 3,
wherein when the line width of two linear portions forming each of the bent portions is D and the radius of curvature of the recessed arc-shaped bottom edge is R1, the relational expression 0.5≤L1≤2 holds when L1=R1/D.

6. The stretchable wiring board according to claim 1,
wherein the line width D of two linear portions forming each of the bent portions is 3 mm or less.

7. The stretchable wiring board according to claim 2,
wherein the line width D of two linear portions forming each of the bent portions is 3 mm or less.

8. The stretchable wiring board according to claim 1,
wherein the stretchable wiring contains a resin and flake-shaped metal powder, has an elongation at break of 130% or more, and has a resin percentage of 8 wt % to 20 wt %.

9. The stretchable wiring board according to claim 2,
wherein the stretchable wiring contains a resin and flake-shaped metal powder, has an elongation at break of 130% or more, and has a resin percentage of 8 wt % to 20 wt %.

10. The stretchable wiring board according to claim 1,
wherein the stretchable wiring contains a resin having a monomer unit structure identical to that of the resin.

11. The stretchable wiring board according to claim 2,
wherein the stretchable wiring contains a resin having a monomer unit structure identical to that of the resin.

12. A stretchable device in which the stretchable wiring board according to claim 1 is used.

13. A stretchable device in which the stretchable wiring board according to claim 2 is used.

14. A stretchable device in which the stretchable wiring board according to claim 3 is used.

15. A stretchable device in which the stretchable wiring board according to claim 4 is used.

16. A stretchable device in which the stretchable wiring board according to claim 5 is used.

17. A stretchable device in which the stretchable wiring board according to claim 6 is used.

18. A stretchable device in which the stretchable wiring board according to claim 7 is used.

19. A stretchable device in which the stretchable wiring board according to claim 8 is used.

20. A stretchable device in which the stretchable wiring board according to claim 9 is used.
